(19) United States
(12) Patent Application Publication
(10) Pub. No.: US 2024/0253912 A1
(43) Pub. Date: Aug. 1, 2024

(54) ROBOT

(71) Applicant: KAWASAKI JUKOGYO KABUSHIKI KAISHA, Kobe-shi, Hyogo (JP)

(72) Inventors: Yuji TANAKA, Kobe-shi (JP); Kazushi MISAO, Kobe-shi (JP)

(73) Assignee: KAWASAKI JUKOGYO KABUSHIKI KAISHA, Kobe-shi, Hyogo (JP)

(21) Appl. No.: 18/560,466

(22) PCT Filed: Jul. 13, 2022
(86) PCT No.: PCT/JP2022/027606

§ 371 Date: Nov. 13, 2023

(30) Foreign Application Priority Data
Aug. 5, 2021 (JP) 2021-129011

(51) Int. Cl. B65G 47/90; H01L 21/687

(52) U.S. Cl. CPC B65G 47/90; H01L 21/68707

(57) ABSTRACT

A substrate conveyor robot (100) according to this disclosure includes the robot cable (40) including a plurality of wires (41), and a tube-shaped part (42) that covers the plurality of wires (41) with play of the plurality of wires in the tube-shaped part. The plurality of wires (41) are aligned side by side in the tube-shaped part (42).

### TECHNICAL FIELD

The present disclosure relates to a robot, in particular, to a robot including a robot cables.

### BACKGROUND ART

A Cableveyor device for accommodating cables is known in the art. Such a Cableveyor device is disclosed in Japanese Patent Laid-Open Publication No. JP H05-69381, for example.

Japanese Patent Laid-Open Publication No. JP H05-69381 discloses a Cableveyor device including a circular rotating frame and a circular stationary frame arranged outside the rotating frame. In this Cableveyor device, a Cableveyor (registered trademark) is arranged in an S-shape between the rotating frame and the stationary frame. One end of the Cableveyor is fixed to the rotating frame. Another end of the Cableveyor is fixed to the stationary frame. The Cableveyor accommodates a plurality of cables. The cables extend in an S-shape correspondingly extending along the S-shaped Cableveyor. The stationary frame is fixed, while the rotating frame can rotate. When the rotating frame rotates, one end of the Cableveyor is moved together with the rotating frame. Accordingly, the Cableveyor deforms from the S-shape to a J-shape. The plurality of cables accommodated in the Cableveyor correspondingly deform into a J-shape. In other words, deformation of the Cableveyor deforms the plurality of cables.

### PRIOR ART

### Patent Document

Patent Document 1: Japanese Patent Laid-Open Publication No. JP H05-69381

### SUMMARY OF THE INVENTION

Although not stated in Japanese Patent Laid-Open Publication No. JP H05-69381, each cable generally includes a plurality of wires and a plurality of sheaths each of which covers one of the wires. The sheath means an outer covering. Also, in general, each of the plurality of wires are arranged in one of the sheaths without play so that the wire cannot smoothly move. In a case in which the cables are deformed as the Cableveyor deforms in Japanese Patent Laid-Open Publication No. JP H05-69381, each wire in the cable can have a relatively small radius of curvature. If the curvature radius of the wire, which is arranged without play in the sheath, is relatively small, there is no space into which the deformed wire moves to relieve its curvature. For this reason, a stress is concentratedly applied to the deformed part of the wire, and can cause a kink in the wire. The kink refers to twist, torsion, tangle, etc. Although it is not stated in Japanese Patent Laid-Open Publication No. JP H05-69381, in general, a relatively large number of wires are bundled together into one bundle. Accordingly, in a case in which the cables are deformed as the Cableveyor deforms in Japanese Patent Laid-Open Publication No. JP H05-69381, inner-side wires will push and expand outer-side wires in the relatively large number of wires bundled into one bundle. As a result, a kink may be formed in outer-side wires. When the cable is deformed, the wires may be torn off caused by such a kink in the wires. This problem also arises in a case in which such a Cableveyor device disclosed in Japanese Patent Laid-Open Publication No. JP H05-69381 is used in a robot.

The present disclosure is intended to solve the above problem, and one object of the present disclosure is to provide a robot capable of preventing wires in a robot cable from being torn off even if the robot cable is deformed.

In order to attain the aforementioned object, a robot according to one aspect of the present disclosure is a robot to be arranged in a clean room, the robot including a robot cable that is arranged in at least one of an arm to which a linearly movable hand is attached, a columnar housing including an upward/downward mover configured to move an/the arm upward/downward, and a horizontal base configured to move a/the housing in a horizontal direction, wherein the robot cable includes a plurality of wires, and a tube-shaped part that covers the plurality of wires with play of the plurality of wires in the tube-shaped part; and the plurality of wires are aligned side by side in the tube-shaped part.

In the robot according to the one aspect of the present disclosure, as discussed above, the tube-shaped part covers the plurality of wires with play of the plurality of wires in the tube-shaped part. Accordingly, even if the robot cable is deformed, the tube-shaped part can have space into which the wires deformed by deformation of the robot cable move to relieve their curvature. As a result, it is possible to prevent a kink caused by lack of space into which the deformed wires move to relieve their curvature. In addition, the plurality of wires are aligned side by side in the tube-shaped part. As a result, dissimilar to a case in which a relatively large number of wires are twisted together to form one bundle, inner-side wires do not push and expand outer-side wires. Consequently, it is possible to prevent a kink caused by expansion of the outer-side wires by the inner-side wires. Therefore, it is possible to prevent the wires in the robot cable from being torn off even if the robot cable is deformed.

According to this disclosure, it is possible to prevent the wires in the robot cable from being torn off even if the robot cable is deformed as discussed above.

### BRIEF DESCRIPTION OF THE DRAWINGS

FIG. 1 is a side view of a substrate conveyor robot according to one embodiment.

FIG. 2 is a cross-sectional view of a robot cable taken along a plane extending in a shorter direction of the robot cable according to the one embodiment.

FIG. 3 is a diagram showing a pair of twisted cables.

FIG. 4 is a cross-sectional view of the robot cable taken along a plane extending in a longitudinal direction of the robot cable according to the one embodiment.

FIG. 5 is a cross-sectional view showing the curved robot cable according to the one embodiment.

FIG. 6 is a cross-sectional view of a robot cable taken along a plane extending in a shorter direction of the robot cable according to a first modified embodiment.

FIG. 7 is a cross-sectional view of a robot cable taken along a plane extending in a longitudinal direction of the robot cable according to a second modified embodiment.

FIG. 8 is a cross-sectional view of a robot cable taken along a plane extending in a longitudinal direction of the robot cable according to a third modified embodiment.

FIG. 9 is a cross-sectional view of a robot cable taken along a plane extending in a shorter direction of the robot cable according to a fourth modified embodiment.

FIG. 10 is a diagram showing a substrate conveyor robot according to a modified embodiment.

### MODES FOR CARRYING OUT THE INVENTION

One embodiment embodying the present disclosure will be described with reference to the drawings.

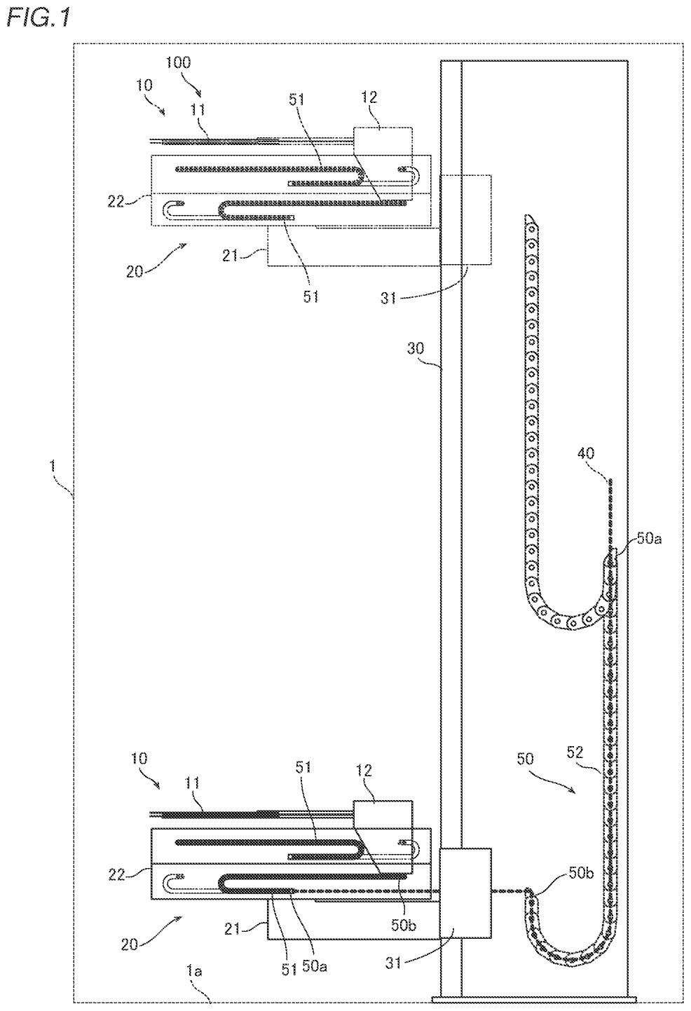

The following description describes configurations of a substrate conveyor robot 100 according to an embodiment with reference to FIGS. 1 to 5. The substrate conveyor robot 100 is an example of a robot.

As shown in FIG. 1, the substrate conveyor robot 100 includes a hand 10 configured to hold a substrate of a semiconductor wafer, and an arm 20 configured to move the hand 10. The hand 10 is attached to the arm 20. The arm 20 includes a first arm 21 attached to an upward/downward mover 31, which will be described later, and a second arm 22 arranged above the first arm 21. The substrate conveyor robot 100 may convey a package substrate, a glass substrate, a panel and a maintenance part such as a focus ring, etc., other than the semiconductor wafer, for example,

The hand 10 is attached to the arm 20, and configured to linearly move. Specifically, the hand 10 can linearly move in a horizontal direction. The hand 10 includes holders 11 configured to hold the substrate, and a mount 12 supporting the holders 11 attached thereto and configured to slide on the second arm 22. Two holders 11 are attached the mount 12 with overlapping each other as viewed in an upward/downward direction.

The substrate conveyor robot 100 includes a columnar housing 30 including an upward/downward mover 31 configured to move the arm 20 upward/downward. The upward/downward mover 31 can move upward/downward along one edge of the housing 30. The arm 20 is attached to the upward/downward mover 31. Accordingly, the arm 20 is configured to move together with the upward/downward mover 31 upward/downward.

In this embodiment, the substrate conveyor robot 100 includes a robot cable 40. The robot cable 40 is arranged in the arm 20, and is configured to move together with the linearly movable hand 10. The robot cable 40 is accommodated in the housing 30, and is configured to move together with the arm 20 moving upward/downward. Specifically, one end of the robot cable 40 is connected to a control board, a power supply board, etc., provided in the arm 20. The robot cable 40 extends in the arm 20 into the upward/downward mover 31. The robot cable 40 extending from the passes arm 20 through the upward/downward mover 31, and extends into the housing 30. Another end of the robot cable 40 includes a connector connected thereto. The connector of the robot cable 40 is connected to a connector of a cable that extends from a robot controller.

In this embodiment, the substrate conveyor robot 100 includes a cable guide 50. The cable guide 50 accommodates the robot cable 40, and is configured to deform to follow the robot cable 40 when the robot cable moves. The cable guide 50 includes, for example, Cableveyor (registered trademark). The cable guide 50 is arranged in the arm 20 and the housing 30. The cable guide 50 includes cable guides 51 arranged in the arm 20. Two cable guides 51 are accommodated in the arm 20. The cable guide 50 includes a cable guide 52 arranged in the housing 30. One end 50a of the cable guide 50 is a fixed end, while another end 50b is a movable end. The robot cable 40 extends across the two cable guides 51 and the cable guide 52.

Another end 50b of the cable guide 51 moves as the hand 10 linearly moves in the horizontal direction. In this movement, a shape of the cable guide 51 changes. A shape of the robot cable 40 correspondingly changes as the shape of the cable guide 51 changes. The cable guide 51 after moving is indicated by two-dot chain lines.

Another end 50b of the cable guide 52 moves as the arm 20 moves upward/downward in a vertical direction. In this movement, a shape of the cable guide 52 changes. A shape of the robot cable 40 correspondingly changes as the shape of the cable guide 52 changes. The cable guide 52, the hand 10 and the arm 20 after moving are indicated by two-dot chain lines.

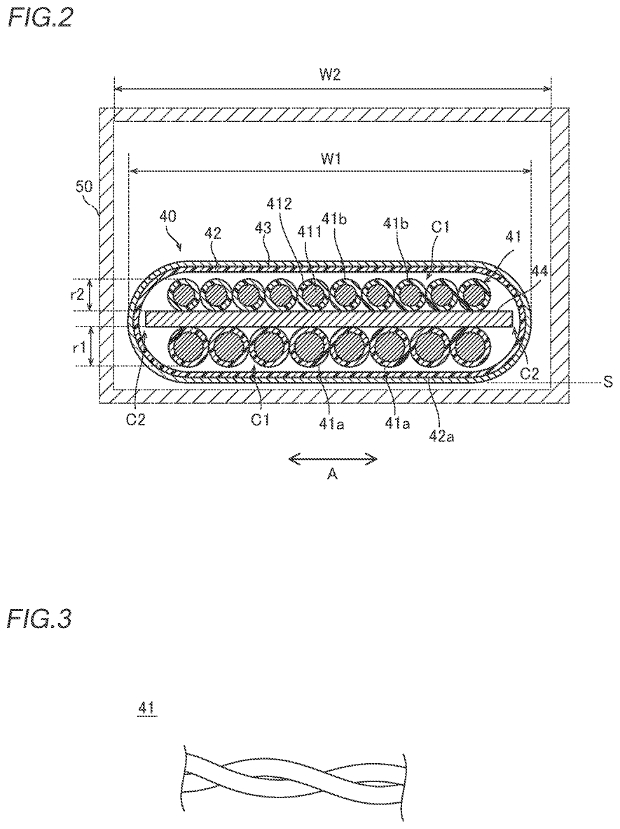

In this embodiment, as shown in FIG. 2, the robot cable 40 includes a plurality of wires 41, and a tube-shaped part 42 that covers the plurality of wires 41 with play. The plurality of wires 41 are aligned side by side in the tube-shaped part 42. Each wire 41 includes a conductor 411 formed of copper, etc., and an electrically insulating covering 412 covering the conductor 411. Each wire 41 can include a single conductor, or a twisted pair cable constructed of two stranded conductors as shown in FIG. 3. The cable refers to a composite cable including a plurality of wires 41 and a sheath covering the plurality of wires 41. The tube-shaped part 42 is a sheath. The play refers an arrangement in which interspaces C1 between the tube-shaped part 42 and wires 41 are produced. Each interspace C1 is smaller than a diameter of each wire 41, for example. The diameter of wire 41 is a diameter r1 of a first wire 41a or a diameter r2 of the second wire 41b, which will be discussed later.

In this embodiment, the tube-shaped part 42 thermally shrinks. For example, the tube-shaped part 42 is formed of polyolefin.

In this embodiment, the tube-shaped part 42 is formed of a transparent material. For example, the tube-shaped part 42 is formed of transparent polyolefin.

An outside of the tube-shaped part 42 is covered by braided wire 43. The braided wire 43 is constructed of a mesh of copper wires and fibers. The braided wire 43 can shield electrical noises.

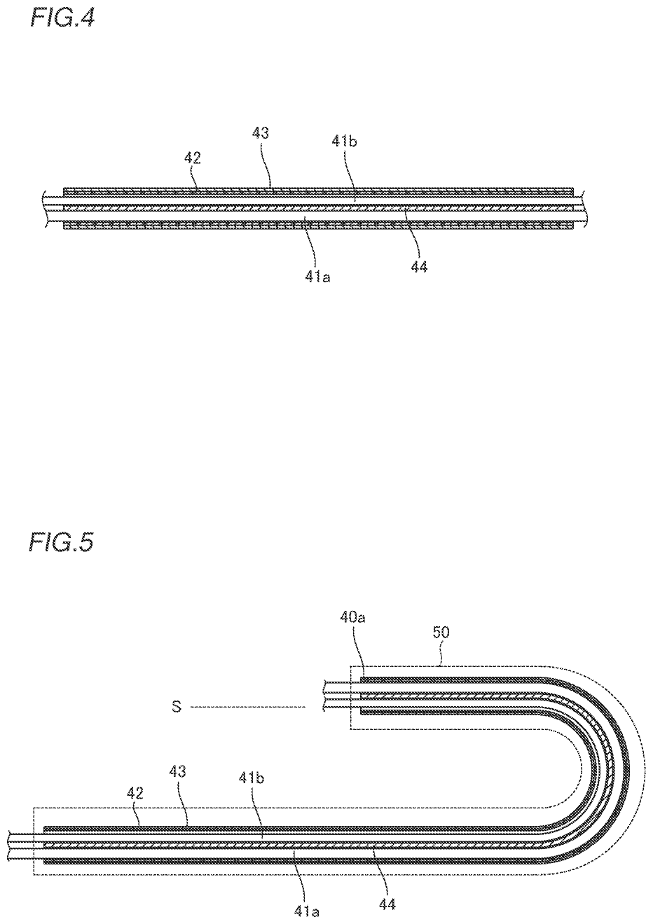

In this embodiment, as shown in FIG. 4, at least one end of the tube-shaped part 42, which covers the plurality of wires 41, is fastened to the plurality of wires 41. Specifically, the at least one end of the tube-shaped part 42 is fastened to the plurality of wires 41 by shrinking. In more detail, the tube-shaped part 42 substantially entirely thermally shrinks. The one end of the tube-shaped part 42 is an end of the tube-shaped part 42 in a longitudinal direction in which the tube-shaped part extends.

In this embodiment, the tube-shaped part 42 has a flattened shape in a cross-sectional view as shown in FIG. 2. In this embodiment, the tube-shaped part 42 has a circular shape in a cross-sectional view before shrinking. The circular shape of the tube-shaped part 42 can be changed to the flattened shape in a cross-sectional view after shrinking by providing a sheet-shaped part 44, which will be discussed later, inside the tube-shaped part 42. A width W1 of the the tube-shaped part 42 in a cross-sectional view in a direction A is slightly smaller than a width W2 of an area of the cable guide 50 in which the robot cable 40 is accommodated. The direction A is a major axis direction of the flatten tube-shaped part 42 in a cross-sectional view. As a result, in a case in which an air pipe other than the robot cable 40 is accommodated in the cable guide 50, it is possible to prevent the robot cable 40 from overlying the air pipe.

In this embodiment, the movable end 40a of the robot cable 40 slidably moves as shown in FIGS. 1 and 5. As shown in FIG. 2, a flat surface 42a of the tube-shaped part 42 having the flatten shape faces a surface S on which the robot cable 40 slides. Specifically, the movable end 40a of the robot cable 40, which is located inside the cable guide 51 in FIG. 1, slides along the horizontal plane. The flat surface 42a of the tube-shaped part 42, which is arranged in the cable guide 51, faces a horizontal plane. Also, the movable end 40a of the robot cable 40, which is arranged in the cable guide 52 in FIG. 1, can slides along a vertical plane. The flat surface 42a of tube-shaped part 42, which is arranged in the cable guide 52 in FIG. 1, faces the vertical plane.

In this embodiment, the robot cable 40 further includes the sheet-shaped part 44 arranged in the tube-shaped part 42, and the plurality of wires 41 are placed on the sheet-shaped part. For example, the sheet-shaped part 44 is formed of ultra-high molecular weight polyethylene (UPE). The sheet-shaped part 44 extends from one end to another end of the tube-shaped part 2 in the longitudinal direction as shown in FIG. 4. As shown in FIG. 2, the sheet-shaped part 44 extends from a point in proximity to one end to a point in proximity to another end of the flatten tube-shaped part 42 in the direction A in a cross-sectional view. An interspace C2 between the sheet-shaped part 44 and tube-shaped parts 42 in the direction A is relatively small. The interspace C2 is smaller than the diameter of the wire 41, for example. The plurality of wires 41 are aligned side by side on a surface of the sheet-shaped part 44.

In this embodiment, the plurality of wires 41 includes two or more first wires 41a and two or more second wires 41b, as shown in FIG. 2. The first wires 41a are aligned side by side on one side of the sheet-shaped part 44 in the tube-shaped part 42. The second wires 41b are aligned side by side on another side of the sheet-shaped part 44 in the tube-shaped part 42. The diameter r1 of each first wire 41a is greater than the diameter r2 of each second wire 41b. The first wires 41a are power supply wires for supplying power, and the second wires 41b are signal wires for transmitting signals, for example. The first wires 41a are arranged on a radially outside of the robot cable with the cable guide 50 being curved as shown in FIG. 5. The second wires 41b are arranged on a radially inner of the robot cable with the cable guide 50 being curved. Accordingly, a radius of curvature of each first wire 41a is greater than a radius of curvature of each second wire 41b when the cable guide 50 is curved.

In this embodiment, the substrate conveyor robot 100 is installed in a clean room 1 as shown in FIG. 1. A fan is arranged in the housing 30, and is configured to exhaust air inside the housing 30 to the outside. The air exhausted by the fan is discharged through an opening formed in a floor surface 1a of the housing 30 downward from the clean room 1. The housing 30 of the substrate conveyor robot 100 is fixed onto the floor surface 1a of the clean room 1.

### Advantages of the Embodiment

In this embodiment, as described above, tube-shaped part 42 covers the plurality of wires 41 with play. Accordingly, even if the robot cable 40 is deformed, the tube-shaped part 42 can have space into which the wires 41 deformed by deformation of the robot cable 40 move to relieve their curvature. As a result, it is possible to prevent a kink caused by lack of space into which the deformed wires 41 move to relieve their curvature. In addition, the plurality of wires 41 are aligned side by side in the tube-shaped part 42. As a result, dissimilar to a case in which a relatively large number of wires 41 are twisted together to form one bundle, inner-side wires 41 do not push and expand outer-side wires 41. Consequently, it is possible to prevent a kink caused by expansion of the outer-side wires 41 by the inner-side wires 41. Therefore, it is possible to prevent the wires 41 in the robot cable 40 from being torn off even if the robot cable 40 is deformed.

In this embodiment, as discussed above, the substrate conveyor robot 100 includes the cable guides 50 that accommodates the robot cable 40, and is configured to deform to follow the robot cable 40 when the robot cable moves. Consequently, it is possible to prevent the wires 41 in the robot cable 40 from being torn off even if the robot cable 40 is deformed as the cable guide 50 is deformed. Because the plurality of wires 41 are covered by the tube-shaped part 42, even if the robot cable 40 is arranged in the cable guide 50, it is possible to prevent damage to the wire 41 caused by contact between the robot cable 40 and the cable guide 50.

In this embodiment, as discussed above, at least one end of the tube-shaped part 42, which covers the plurality of wires 41, is fastened to the plurality of wires 41. Accordingly, it is possible to reduce positional deviation of the tube-shaped part 42 with respect to the plurality of wires 41.

In this embodiment, as discussed above, the at least one end of the tube-shaped part 42 is fastened to the plurality of wires 41 by shrinking. Because the plurality of wires 41 are held together by the shrinking end of the tube-shaped part 42, it is possible to prevent the plurality of wires 41 from coming apart. In this embodiment, the tube-shaped part 42, which covers the plurality of wires 41, entirely shrinks. Accordingly, it is possible to prevent the plurality of wires 41 from coming apart and to further reduce positional deviation of the tube-shaped part 42 with respect to the plurality of wires 41.

In this embodiment, as discussed above, the robot cable 40 further includes the sheet-shaped part 44 arranged in the tube-shaped part 42, and the plurality of wires 41 are placed on the sheet-shaped part. Because the plurality of wires 41 are aligned side by side on a surface of the sheet-shaped part 44, it is possible to easily keep the alignment of the plurality of wires 41 side by side in the tube-shaped part 42. Also, when the tube-shaped part 42 shrinks, the sheet-shaped part 44 can prevent the plurality of wires 41, which are aligned side by side, from coming apart.

In this embodiment, as discussed above, the plurality of wires 41 include two or more first wires 41a that are aligned side by side on one side of the sheet-shaped part 44 in the tube-shaped part 42, and two or more second wires 41b that are aligned side by side on another side of the sheet-shaped part 44 in the tube-shaped part 42. Accordingly, it is possible to prevent different types of the first wires 41a and the second wires 41b from being mixed in the tube-shaped part 42. In addition, the first wires 41a having a large diameter of r1 are arranged on the radially outside of the robot cable, and the second wires 41b having a large diameter of r2 are arranged on the radially inside of the robot cable when the robot cable 40 is curved. Because the first wires 41a whose permissible radius of curvature is larger are are arranged on the radially outside of the robot cable, it is possible to prevent a kink from being formed in the first wire 41a when the robot cable 40 is curved.

In this embodiment, as discussed above, the tube-shaped part 42 thermally shrinks. Accordingly, the tube-shaped part 42 can easily shrink by applying heat to the tube-shaped part. Because the tube-shaped part 42 has a relatively large diameter before thermally shrinking, the plurality of wires 41 can be easily inserted into the tube-shaped part 42.

In this embodiment, as discussed above, the tube-shaped part 42 has a flattened shape in a cross-sectional view. Accordingly, it is possible to easily bend the robot cable 40 while keeping the alignment of the plurality of wires 41 side by side in the tube-shaped part 42. In addition, play of the plurality of wires 41 inside the tube-shaped part 42 can be relatively small as compared to a case in which the tube-shaped part 42 has a circular shape in a cross-sectional view. For this reason, it is possible to prevent one wire 41 in the plurality of wires 41 from overlying other wires 41 while surely providing the plurality of wires 41 with enough play to move the plurality of wires. Consequently, it is possible to prevent a kink caused by deformation of the plurality of wires with one wire 41 overlying other wires 41. Also, because the tube-shaped part 42 has a flattened shape in a cross-sectional view, a thickness of the robot cable 40 can be relatively small so that a height of the cable guide 50 configured to guide the robot cable 40 can be small.

In this embodiment, as discussed above, the movable end 40a of the robot cable 40 slidably moves; and the flat surface 42a of the tube-shaped part 42 having the flatten shape faces the surface S on which the robot cable 40 slides. Accordingly, the robot cable 40 can be stably placed on the surface S. Consequently, unintended deformation of the robot cable 40, such as torsion of the robot cable 40, can be prevented when the robot cable 40 is moved.

In this embodiment, as discussed above, the tube-shaped part 42 is formed of a transparent material. Accordingly, because the wires 41 inside the tube-shaped part 42 can be seen, even after the plurality of wires 41 are covered by the tube-shaped part 42, conditions of the wires 41 can be confirmed.

In this embodiment, as discussed above, the substrate conveyor robot 100 is installed in a clean room 1. Here, the substrate conveyor robot 100 that is installed in the clean room 1 repeats operations or a large number of times in some cases. In such a case, the robot cable 40 repeatedly deforms. From this viewpoint, because the plurality of wires 41 are held in the tube-shaped part 42 with play of the plurality of wires in the tube-shaped part and with the plurality of wires being aligned side by side whereby preventing a kink from being formed in the plurality of wires as described above, it is possible to reduce a frequency of maintenance of the robot cable 40 of the substrate conveyor robot 100, and such reduction of a frequency of maintenance is very effective particularly for the robot cable of the substrate conveyor robot installed in the clean room 1 where users cannot easily perform maintenance.

In this embodiment, as discussed above, the robot cable 40 is arranged in the arm 20 to which the linearly movable hand 10 is attached, and is configured to move together with the linearly movable hand 10. The linearly movable hand 10 repeatedly linearly moves. In this case, the robot cable 40 repeatedly deforms. From this viewpoint, because the plurality of wires 41 are held in the tube-shaped part 42 with play of the plurality of wires in the tube-shaped part and with the plurality of wires being aligned side by side whereby preventing a kink from being formed in the plurality of wires as described above, such prevention of a kink is very effective particularly for the robot cables 40, which moves together with the linearly movable hand 10.

In this embodiment, as discussed above, the robot cable 40 extends from the arm 20 into the housing 30, and is configured to move together with the arm 20 moving upward/downward. The arm 20 repeatedly moves upward/downward in some cases. In such a case, the robot cable 40 repeatedly deforms. From this viewpoint, because the plurality of wires 41 are held in the tube-shaped part 42 with play of the plurality of wires in the tube-shaped part and with the plurality of wires being aligned side by side whereby preventing a kink from being formed in the plurality of wires as described above, such prevention of a kink is very effective particularly for the robot cables 40, which moves together with the arm 20 moving upward/downward.

### Modified Embodiments

Note that the embodiment disclosed this time must be considered as illustrative in all points and not restrictive. The scope of the present disclosure is not shown by the above description of the embodiments but by the scope of claims for patent, and all modifications or modified examples within the meaning and scope equivalent to the scope of claims for patent are further included.

While the example in which the robot cable 40 is arranged in the arm 20, and the housing 30, which includes the upward/downward mover 31, has been shown in the aforementioned embodiment, the present disclosure is not limited to this. For example, the robot cable 40 may be arranged only in the arm 20, only in the housing 30, which includes the upward/downward mover 31, or only in a horizontal base 60, which will be described below. Alternatively, the robot cable 40 may be arranged in two of the arm 20, the housing 30, which includes the upward/downward mover 31, and the horizontal base 60, which will be described below.

While the example in which the robot cable 40 is arranged in the cable guide 50 has been shown in the aforementioned embodiment, the present disclosure is not limited to this. For example, the cable guide 50 may not be provided. For example, the robot cable 40 may be moved and deformed with one end of the robot cable 40 serving as a fixed end and another end serving as a movable end without the cable guide 50.

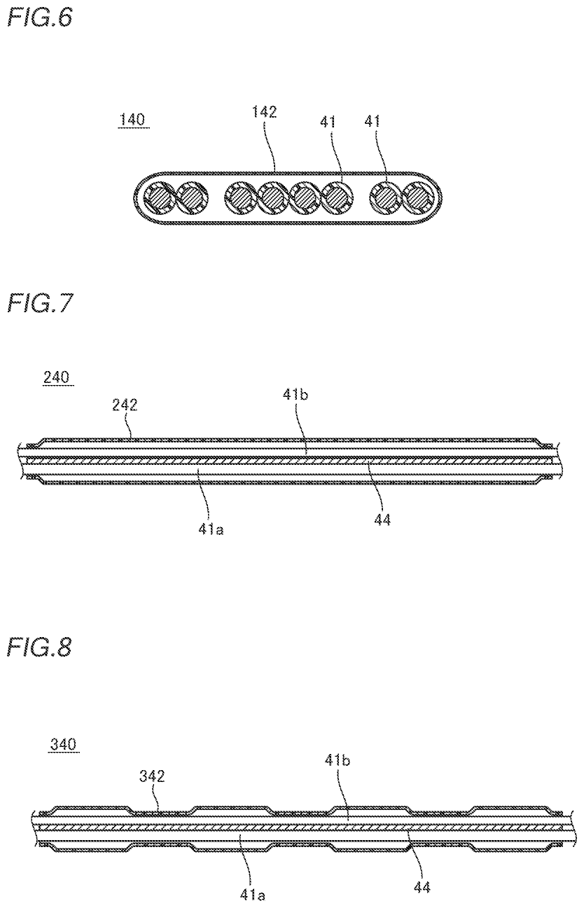

While the example in which the sheet-shaped part 44 is arranged in the tube-shaped part 42 has been shown in the aforementioned embodiment, the present disclosure is not limited to this. For example, the sheet-shaped part 44 may not be arranged in a tube-shaped part 142 as shown in a robot cable 140 according to a first modified embodiment of FIG. 6. Also, in the first modified embodiment, the plurality of wires 41 are aligned side by side in the tube-shaped part 142. The tube-shaped part 142 has a flattened shape in a cross-sectional view.

While the example in which the outside of the tube-shaped part 42 is covered by the braided wire 43 has been shown in the aforementioned embodiment, the present disclosure is not limited to this. For example, the outside of the tube-shaped part 142 may not be covered by the braided wire 43 as shown in the robot cable 140 according to the first modified embodiment of FIG. 6.

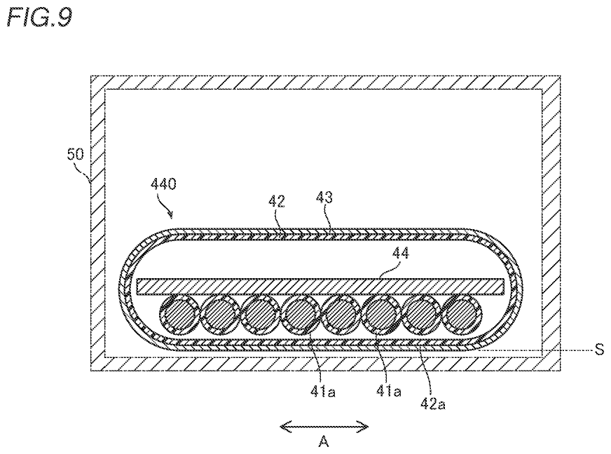

While the example in which the tube-shaped part 42 substantially entirely thermally shrinks has been shown in the aforementioned embodiment, the present disclosure is not limited to this. For example, only ends of the tube-shaped part 242 may thermally shrink as shown in a robot cable 240 according to a second modified embodiment of FIG. 7. Although both the ends of the tube-shaped part 242 are thermally shrink in FIG. 7, one of the ends may thermally shrink. Alternatively, parts of a tube-shaped part 342 may thermally shrink in addition to the ends of the tube-shaped part 342 as shown in a robot cable 340 according to a third modified embodiment of FIG. 8. Although the braided wire 43 is not illustratively provided in FIGS. 7 and 8, an outside of the tube-shaped part 242 or the tube-shaped part 342 may be covered by the braided wire 43.

While the example in which the tube-shaped part 42 thermally shrinks has been shown in the aforementioned embodiment, the present disclosure is not limited to this. For example, the tube-shaped part 42 may shrink by other means other than heat.

While the example in which the tube-shaped part 42 is fastened to the plurality of wires 41 by thermally shrinking has been shown in the aforementioned embodiment, the present disclosure is not limited to this. For example, the plurality of wires 41 may be arranged in a tube-shaped part that cannot thermally shrink, and the tube-shaped part may be secured to the plurality of wires 41 by tying at least one end of the tube-shaped part, which cannot thermally shrink, by a tie, etc.

While the example in which the tube-shaped part 42 has a flattened shape in a cross-sectional view has been shown in the aforementioned embodiment, the present disclosure is not limited to this. For example, the tube-shaped part 42 may have a circular shape in a cross-sectional view.

While the example in which the tube-shaped part 42 is formed of a transparent material has been shown in the aforementioned embodiment, the present disclosure is not limited to this. For example, the tube-shaped part 42 may be colored.

While the example in which the substrate conveyor robot 100 is installed in a clean room 1 has been shown in the aforementioned embodiment, the present disclosure is not limited to this. The present disclosure can be applied to the substrate conveyor robot 100 installed in a place other than the clean room 1.

While the example in which the present disclosure is applied to the substrate conveyor robot 100 has been shown in the aforementioned embodiment, the present disclosure is not limited to this. The present disclosure can be applied to a robot other than the substrate conveyor robot 100.

While the example in which the plurality of first wires 41a are arranged on one side of the sheet-shaped part 44, and the second wires 41b are arranged on another side of the sheet-shaped part has been shown in the aforementioned embodiment, the present disclosure is not limited to this. For example, the wires 41 may be arranged only on one side of the sheet-shaped part 44 as shown in a robot cable 440 according to a fourth modified embodiment of FIG. 9. FIG. 9 is a cross-sectional view showing the robot cable 40 in which the first wires 41a are arranged on a surface S side on which the robot cable slides.

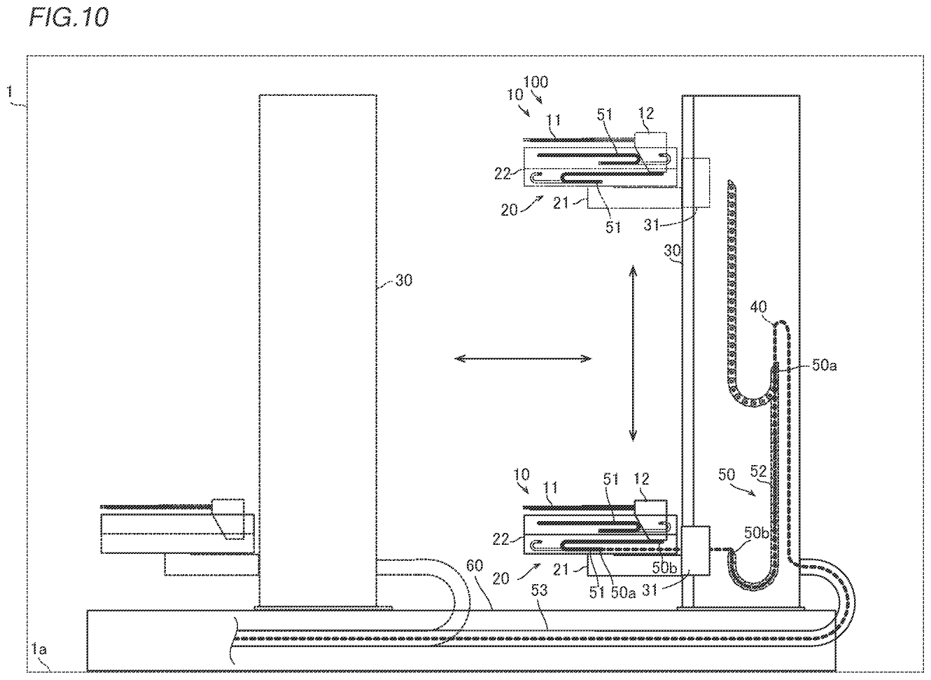

While the example in which the housing 30 of the substrate conveyor robot 100 is fixed onto the floor surface 1a of the clean room 1 has been shown in the aforementioned embodiment, the present disclosure is not limited to this. For example, the housing 30 of the substrate conveyor robot 100 may be arranged on a horizontal base 60 as shown in FIG. 10. The horizontal base 60 is configured to move the housing 30 in a horizontal direction. The robot cable 40 is arranged in the arm 20, and is configured to move together with the linearly movable hand 10. The robot cable 40 is accommodated in the housing 30, and is configured to move together with the arm 20 moving upward/downward. The robot cable 40 is arranged in the horizontal base 60, and is configured to move together with horizontal movement of the housing 30. The robot cable 40 is arranged in the cable guide 50. The cable guide 50 includes a cable guide 51 that is arranged in the arm 20, a cable guide 52 that is arranged in the housing 30, and a cable guide 53 that is arranged in the horizontal base 60.

### DESCRIPTION OF REFERENCE NUMERALS

1; clean room
10; hand
20; arm
30; housing
31; upward/downward mover
40, 140, 240, 340, 440; robot cable
40a; movable end
41; wire
41a; first wire
41b; second wire
42, 142, 242, 342; tube-shaped part
44; sheet-shaped part
50, 51, 52, 53; cable guide
60; horizontal base
100; substrate conveyor robot (robot)
S; surface

1. A robot to be arranged in a clean room, the robot comprising
a robot cable that is arranged in at least one of an arm to which a linearly movable hand is attached, a columnar housing including an upward/downward mover configured to move an/the arm upward/downward, and a horizontal base configured to move a/the housing in a horizontal direction, wherein
the robot cable includes
a plurality of wires, and
a tube-shaped part that covers the plurality of wires with play of the plurality of wires in the tube-shaped part; and
the plurality of wires are aligned side by side in the tube-shaped part.

2. The robot according to claim 1 further comprising a cable guide that accommodates the robot cable, and is configured to deform to follow the robot cable when the robot cable moves.

3. The robot according to claim 1, wherein at least one end of the tube-shaped part, which covers the plurality of wires, is fastened to the plurality of wires.

4. The robot according to claim 3, wherein the at least one end of the tube-shaped part is fastened to the plurality of wires by shrinking.

5. The robot according to claim 1, wherein the robot cable further includes a sheet-shaped part arranged in the tube-shaped part, and the plurality of wires are placed on the sheet-shaped part.

6. The robot according to claim 5, wherein
the plurality of wires includes
two or more first wires that are aligned side by side on one side of the sheet-shaped part in the tube-shaped part, and
two or more second wires that are aligned side by side on another side of the sheet-shaped part in the tube-shaped part.

7. The robot according to claim 1, wherein the tube-shaped part thermally shrinks.

8. The robot according to claim 1, wherein the tube-shaped part has a flattened shape in a cross-sectional view.

9. The robot according to claim 8, wherein
a movable end of the robot cable slidably moves; and
a flat surface of the tube-shaped part having the flatten shape faces a surface on which the robot cable slides.

10. The robot according to claim 1, wherein the tube-shaped part is formed of a transparent material.

11. The robot according to claim 1 comprising
the arms, and
the linearly movable hand, which is attached to the arm, wherein
the robot cable is arranged in the arm, and is configured to move together with the linearly movable hand.

12. The robot according to claim 1 comprising
the arms, and
the columnar housing, which include the upward/downward mover configured to move the arm upward/downward, wherein
the robot cable extends from the arm into the housing, and is configured to move together with the arm moving upward/downward.

13. The robot according to claim 1 comprising
the arms,
the columnar housing, which include the upward/downward mover configured to move the arm upward/downward, and
the horizontal base, which is configured to move the housing in a horizontal direction, wherein
the robot cable is arranged in the horizontal base, and is configured to move together with the housing moving in the horizontal direction.
